(19) United States
(12) Patent Application Publication
(10) Pub. No.: US 2007/0166868 A1
(43) Pub. Date: Jul. 19, 2007

(54) Method of fabricating an image sensor

(76) Inventors: Teng-Yuan Ko, Jhubei City (TW); Kuo-Lun Tseng, Kaohsiung City (TW); Ho-Sung Liao, Hsinchu City (TW); Wen-Liang Tseng, Longtan Township (TW); Kuo-Fen Sun, Taipei City (TW); Meng-Tsung Chen, Hsinchu City (TW)

Correspondence Address: J.C. Patents, Inc., Suite 250, 4 Venture, Irvine, CA, 92618, US

(21) Appl. No.: 11/326,782

(22) Filed: Jan. 5, 2006

(51) Int. Cl. H01L 21/00

(52) U.S. Cl. 438/70

(57) ABSTRACT

A method of fabricating an image sensor on a semiconductor substrate having a sensor array region is described. A first planar layer is formed on a semiconductor substrate. Then, a color filter array (CFA) is formed on the first planar layer. A second planar layer is formed on the color filter array. Thereafter, a plurality of U-lenses is formed on the second planar layer. A passivation is formed over the second planar layer and the U-lenses by performing a plasma-enhanced chemical vapor deposition (PECVD) process using TEOS gas. The passivation layer is formed under the conditions that include applying radio frequency power at a rating between 250W˜450W and supplying TEOS gas at a mass flow rate of about 150˜500 mg/m.

### BACKGROUND OF THE INVENTION

1. Field of the Invention

The present invention relates to a method of fabricating an image sensor. More particularly, the present invention relates to a method of fabricating an image sensor on a semiconductor substrate.

2. Description of the Related Art

Image sensor is a device designed mainly for converting optical data into electrical signals. In general, image sensors can be roughly categorized into display tube type and still imaging device. The imaging tube centers upon a monitor. The image-processing technique of the imaging tube is widely used for performing measurements, controlling processes and identifying objects.

The still imaging device includes a charged coupled device (CCD) and a complementary metal-oxide-semiconductor (CMOS).

The complementary metal-oxide-semiconductor (CMOS) image sensor is fabricated using CMOS technique. The CMOS image sensor is a device for converting optical images into electrical signals. Similar to the pixel number, a switching mode using MOS transistors and sequential output inspection is deployed. Nowadays, CMOS sensors are often compared with the widely and massively used CCD image sensors. The CMOS sensors have lots of merits. Firstly, the CMOS sensor is easy to drive and can provide a number of scanning modes. Moreover, the signal processing circuits of the CMOS sensors can be fabricated on a single chip to reduce product volume. In addition, the process of fabricating the CMOS sensor is compatible to the CMOS technique so that some production cost can be saved. Furthermore, each CMOS sensor uses very little power so that the sensing device can save considerable electrical power. Due to all these advantages, the CMOS image sensors have overtaken the CCD image sensors as the mainstream image-sensing product in recent years.

However, the U-lenses and the color filter array (CFA) in the CMOS transistor image-sensing device are fabricated using photoresist material with a low ignition point, slightly smaller than 300° C. Therefore, the conventional fabrication method can hardly produce a passivation layer over the U-lenses to prevent micro-particles or other source of contaminants from damaging the surface of the U-lenses. Furthermore since the U-lenses are fabricated using photoresist material, its structure is rather brittle. Thus, the U-lenses frequently receive some structural damages after performing a wafer cleaning operation.

On the other hand, since a gap exists between the U-lenses, dispersed light rays often directly penetrate the gap and shine on an adjacent light-sensitive area leading to undesirable cross-talk. As a result, the amount of noise received by the CMOS transistor image sensors will increase while the average sensing capacity of the image sensors will drop.

### SUMMARY OF THE INVENTION

Accordingly, at least one objective of the present invention is to provide a method of fabricating an image sensor that can prevent the structure of U-lenses from receiving possible damage after a cleaning operation.

At least another objective of the present invention is to provide a method of fabricating an image sensor that can effectively reduce the gap between neighboring U-lenses.

To achieve these and other advantages and in accordance with the purpose of the invention, as embodied and broadly described herein, the invention provides a method of fabricating an image sensor. The image sensor is fabricated on a semiconductor substrate. The semiconductor substrate comprises a sensor array. First, a first planar layer is formed on the semiconductor substrate. Then, a color filter array (CFA) is formed on the first planar layer. The color filter array is formed above the corresponding sensor array area. Thereafter, a second planar layer is formed on the color filter array. After that, a plurality of U-lenses is formed on the second planar layer. The U-lenses are formed in corresponding color filter array areas. A conformal passivation is formed over the U-lenses and the second planar layer by performing a plasma-enhanced chemical vapor deposition (PECVD) process using tetraethosiloxane (TEOS) gas. The passivation layer is formed under the conditions that include applying radio frequency power at a rating between 250 W˜450W and supplying TEOS gas at a mass flow rate of about 150˜500 mg/m.

According to the aforementioned method of fabricating the image sensor in one preferred embodiment of the present invention, the process of forming the passivation layer is carried out at a temperature between 150° C.˜250° C.

According to the aforementioned method of fabricating the image sensor in one preferred embodiment of the present invention, the process of forming the passivation layer includes passing oxygen (O₂) and helium (He).

According to the aforementioned method of fabricating the image sensor in one preferred embodiment of the present invention, the volume flow rate of the oxygen and helium includes 1000 standard cubic centimeter per minute (sccm).

According to the aforementioned method of fabricating the image sensor in one preferred embodiment of the present invention, the image sensor includes a complementary metal-oxide-semiconductor (CMOS) transistor image sensor.

According to the aforementioned method of fabricating the image sensor in one preferred embodiment of the present invention, the color filter array includes a R/G/B color filter array.

According to the aforementioned method of fabricating the image sensor in one preferred embodiment of the present invention, after forming the passivation layer, further includes forming bond pad openings outside the sensor array area.

The present invention also provides an alternative method of fabricating an image sensor. The image sensor is fabricated on a semiconductor substrate. The semiconductor substrate comprises a sensor array. First, a first planar layer is formed on the semiconductor substrate. Then, a color filter array (CFA) is formed on the first planar layer. The color filter array is formed above the corresponding sensor array area. Thereafter, a second planar layer is formed on the color filter array. After that, a plurality of U-lenses is formed on the second planar layer. The U-lenses are formed in corresponding color filter array areas. A conformal passivation is formed over the U-lenses and the second planar layer by performing a plasma-enhanced chemical vapor deposition (PECVD) process using TEOS gas. The passivation layer is formed under the conditions that include applying radio frequency power at a rating between 250 W˜450W, applying a pressure between 2˜4 Torrs and supplying TEOS gas at a mass flow rate between 150˜500 mg/m.

According to the aforementioned method of fabricating the image sensor in one preferred embodiment of the present invention, the process of forming the passivation layer is carried out at a temperature between 150° C.˜250° C.

According to the aforementioned method of fabricating the image sensor in one preferred embodiment of the present invention, the process of forming the passivation layer includes passing oxygen and helium.

According to the aforementioned method of fabricating the image sensor in one preferred embodiment of the present invention, the volume flow rate of the oxygen and helium includes 1000 sccm.

According to the aforementioned method of fabricating the image sensor in one preferred embodiment of the present invention, the image sensor includes a complementary metal-oxide-semiconductor (CMOS) transistor image sensor.

According to the aforementioned method of fabricating the image sensor in one preferred embodiment of the present invention, the color filter array includes a R/G/B color filter array.

According to the aforementioned method of fabricating the image sensor in one preferred embodiment of the present invention, after forming the passivation layer, further includes forming bond pad openings outside the sensor array area.

In the present invention, a passivation layer is formed over the U-lenses in the process of fabricating the image sensor. Hence, micro-particles and other contaminants are prevented from damaging the surface of the U-lenses.

Furthermore, with passivation covering the U-lenses, the U-lenses is structurally protected against any damages during the subsequent wafer cleaning operation.

Moreover the passivation layer can reduce the gaps between neighboring U-lenses. Consequently, the U-lenses not only have a larger area for absorbing incident light, but also reduce cross-talk between the incident light so that the noise received by the CMOS transistor image sensor is reduced and the sensing capacity of the device is increased.

In addition, due to the applied pressure at the condition of the present invention in the process of fabricating the passivation layer, the passivation layer has a smaller stress value. As a result, the chance of producing cracks on the U-lenses is substantially reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the steps for fabricating an image sensor according to one embodiment of the present invention.

FIG. 2 is a photo of a cross-section of the image sensor taken using a scanning electron microscope.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

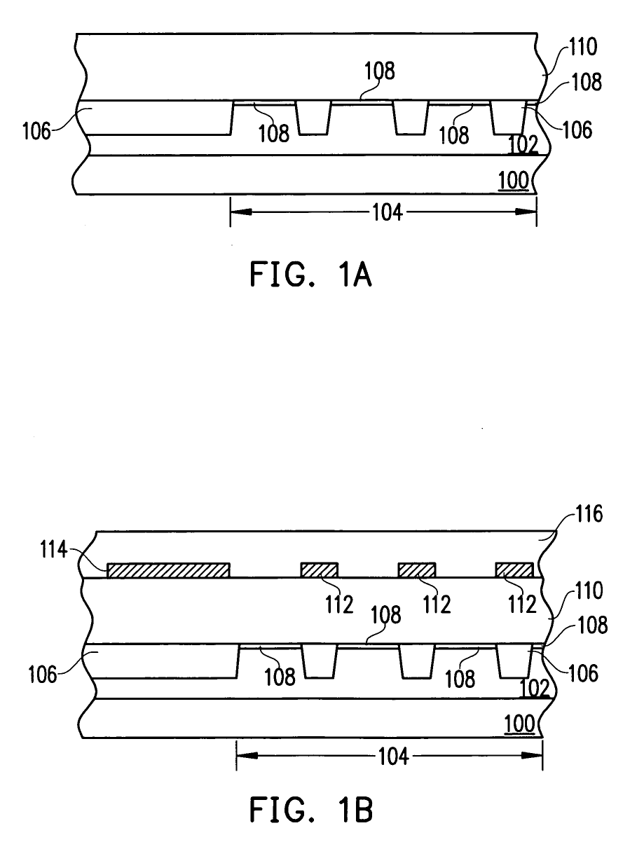

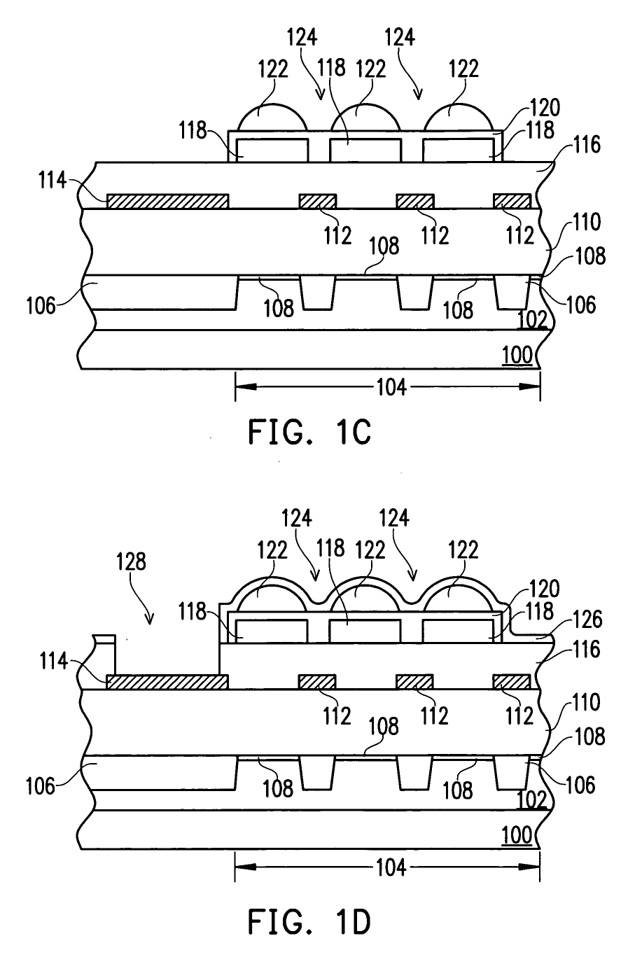

FIGS. 1A through 1D are schematic cross-sectional views showing the steps for fabricating an image sensor according to one embodiment of the present invention. First, as shown in FIG. 1A, a semiconductor substrate 100 such as a silicon substrate is provided. The semiconductor substrate 100 has a P-type well 102 and a sensor array area 104 disposed thereon. The sensor array area 104 has a plurality of light sensing diodes (not shown) disposed on the P-type well 102 and a plurality of isolation structures 106 in the semiconductor substrate 100 disposed between every pair of neighboring light sensing diodes, for example. Furthermore, the isolation structures 106 surrounds the light sensing diodes. Each light sensing diode has a CMOS transistor (not shown) disposed on the surface of the P-type well 102 and a light sensing region 108 formed on a surface layer of the P-type well 102 and electrically connected to the CMOS transistor, for example. The isolation structures 106 are shallow trench isolation (STI) structures, for example.

Thereafter, a planar layer 110 is formed over the semiconductor substrate 100 to cover the light sensitive diodes. The planar layer 110 comprises a silicon-rich oxide (SRO) layer and a spin-on glass layer, for example.

As shown in FIG. 1B, a plurality of patterned metallic layers 112 and 114 is formed on the planar layer 110. The patterned metallic layer 112 is formed in the sensor array area above a corresponding isolation structure 106 for blocking the dispersion of incident light. The patterned metallic layer 114 is formed outside the sensor array area above a corresponding isolation structure 106 to serve as a bond pad metallic layer.

Thereafter, another planar layer 116 is formed over the planar layer 110 and the patterned metallic layers 112 and 114. The planar layer 116 is fabricated using silicon oxide, for example. The method of forming the planar layer 116 includes performing a plasma-enhanced chemical vapor deposition (PECVD) process using tetraethosiloxane (TEOS) as the reactive gas, for example.

In addition, an optional silicon nitride layer (not shown) may form on the planar layer 116 for increasing the stability of the incident light. The method of forming the silicon nitride layer includes performing a plasma-enhanced chemical vapor deposition process, for example.

As shown in FIG. 1C, a color filter array 118 is formed over the planar layer 116 by performing a sequence of operations. The color filter array is a red/green/blue (R/G/B) color filter array, for example. The color filter array 118 is fabricated using a photoresist material, for example. Since the method of forming the color filter array 118 should be familiar to those having general knowledge in this area, a detailed description is omitted.

Thereafter, another planar layer 120 is formed over the color filter array 118. The planar layer 120 is fabricated using a photoresist material, for example.

Then, a plurality of U-lenses 122 is formed on the planar layer 120. The U-lenses 122 are formed above the corresponding color filter array 118. Furthermore, there is a gap 124 between every pair of adjacent U-lenses. The U-lenses 122 are fabricated using a photoresist material, for example.

As shown in FIG. 1D, a plasma-enhanced chemical vapor deposition (PECVD) process is carried out using tetraethosiloxane (TEOS) as the reactive gas to form a conformal passivation layer 126 over the U-lenses 122 and the planar layer 120 that reduces the gaps 124. The passivation layer 126 has a thickness between about 1500˜3000, for example. The passivation layer 126 is formed under the conditions that include applying radio frequency power at a rating between 250 W˜450W and supplying TEOS gas at a mass flow rate of about 150˜500 mg/m. Preferably, the power rating of the radio frequency is about 325 W and the mass flow rate of the TEOS gas is about 240 mg/m. Other conditions for fabricating the passivation layer 126 includes a processing temperature between 150° C.˜250° C., and preferably at a temperature of about 210° C. Furthermore, the process of fabricating the passivation layer 126 may include passing oxygen and helium such that the volume flow rate of oxygen and helium is about 1000 sccm, for example.

In another preferred embodiment, the passivation layer 126 is formed under the conditions that include applying radio frequency power at a rating between 250 W˜450 W, applying a pressure of between 2˜4 Torrs and supplying TEOS gas at a mass flow rate of about 150˜500 mg/m. Preferably, the radio frequency power rating is about 325 W, the pressure is about 2.5 Torrs and the mass flow rate of the TEOS gas is about 240 mg/m. Other conditions for forming the passivation layer 126 include processing at a temperature between 150° C.˜250° C., and preferably at 210° C. Furthermore, the process of fabricating the passivation layer 126 may include passing oxygen and helium. The volume flow rate of oxygen and helium is about 1000 sccm, for example.

It should be noted that the passivation layer 126 fabricated according to the conditions laid down in the present invention would be a uniform layer over the U-lenses 122. Furthermore, the adhesion of the passivation layer 126 with the U-lenses 122 is strong so that the passivation layer 126 is difficult to peel off and has few defects. In addition, the passivation layer 126 will have a rather low stress value, a high uniformity level a high transparence and a low reflection index (RI). The stress value in the passivation layer 126 is typically 2.5×10⁷ dyne/cm², the degree of uniformity is about 3% and the RI is about 1.6, for example.

The optimal range of the parameters (including the radio frequency power rating, the mass flow rate of the TEOS, the processing pressure, the volume flow rate of the oxygen and helium) for forming the passivation layer 126 can be found through the design of experiment (DOE).

After forming the passivation layer 126, a bond pad opening 128 is formed outside the sensor array area 104. The method of forming the bond pad opening 128 includes forming a patterned photoresist layer (not shown) on the passivation layer 126 and performing an etching operation to remove a portion of the passivation layer 126 and the planar layer 116 and expose the patterned metallic layer 114.

Due to the formation of a passivation layer 126 over the U-lenses of the image sensor fabricated according to the method of the present invention, micro-particles or other source of contaminants are prevented from damaging the surface of the U-lenses.

In addition, with the passivation layer 126 over the U-lenses 122, the U-lenses 122 are protected against any damages during the subsequent wafer cleaning operation. Hence, the U-lenses 122 are protected against severe structural damage,

Moreover, the passivation layer 126 can reduce the gap 124 between neighboring U-lenses 122. In some cases, a gapless condition results. Consequently, the U-lenses 122 not only have a larger area for absorbing incident light, but also reduce cross-talk between the incident light so that the noise received by the CMOS transistor image sensor is reduced and the sensing capacity of the device is increased.

In addition, due to the applied pressure in the process of fabricating the passivation layer 126, the passivation layer 126 has a smaller stress value. As a result, the chance of producing cracks on the U-lenses 122 is substantially reduced.

In the following, actual experiments are carried out to obtain some test results for explaining the advantages of using the method in the present invention to fabricate an image sensor.

In an example experiment 1, a passivation layer is formed over the U-lenses at a pressure of 2.5 Torrs, a radio frequency power rating of 325 W, a mass flow rate of TEOS gas of 240 mg/m, a volume flow rate of oxygen and helium of 1000 sccm and a pixel dimension of 3.18 μm and 2.41 μm. Table 1 shows the thickness of the highest point of the U-lenses after forming the passivation layer measured using a scanning electron microscope.

TABLE 1
the thickness of the U-lenses on the wafer

| Wafer location | Pixel dimension (μm) | Thickness (Å) |
|---|---|---|
| Central location | 3.18 | 6050 |
| | 2.4 | 6000 |
| Edge location | 3.18 | 5900 |
| | 2.4 | 6200 |

As shown in Table 1, the U-lenses of the 3.18 μm and 2.4 μm pixel, no matter if they are located in the central location or the edge location of the wafer, receives no compression after forming the passivation layer. In other words, the passivation layer will not damage the U-lenses structure.

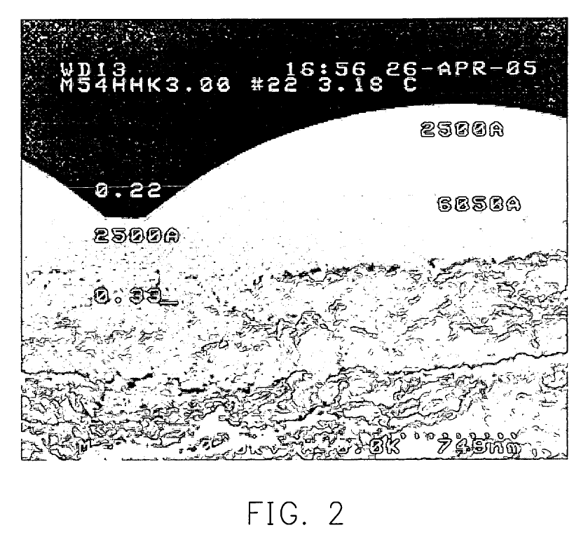

FIG. 2 is a photo of a cross-section of the image sensor taken using a scanning electron microscope. As shown in FIG. 2, using U-lens having a pixel dimension 3.18 μm located in the central location as an example, the portion with 6050 Å labeled on the photo is the thickness of highest point of the U-lens. Similarly, the portion with 2500 Å labeled on the photo is the thickness of the passivation layer. As can be clearly seen in FIG. 2, the U-lens has an intact structure free from any peeling or cracks. In other words, the passivation layer fabricated according to the present invention will not cause any peeling or cracking of the U-lenses.

In another example experiment 2, a passivation layer is formed over the U-lenses at a pressure of 2.5 Torrs, a radio frequency power rating of 325 W, a mass flow rate of TEOS gas of 240 mg/m, a volume flow rate of oxygen and helium of 1000 sccm and a pixel dimension of 3.18 μm and 2.4 μm. Table 2 shows the change in dimension of the surface structure of the U-lenses before and after forming the passivation layer measured using a scanning electron microscope.

TABLE 2
change in surface structure of U-lens

| Before/After | | | | |
|---|---|---|---|---|
| forming the | Pixel | | | Radius of |
| passivation | dimension | | | curvature |
| layer | (μm) | Wafer location | Gap (μm) | (μm) |
| Before forming | 3.18 | Central location | 0.354 | 2.154 |
| the passivation | | Edge location | 0.314 | 2.237 |
| layer | 2.4 | Central location | 0.354 | 1.254 |
| | | Edge location | 0.394 | 1.199 |
| After forming | 3.18 | Central location | 0.196 | 2.444 |
| the passivation | | Edge location | 0.177 | 2.489 |
| layer | 2.4 | Central location | 0.196 | 1.408 |
| | | Edge location | 0.196 | 1.411 |

As shown in Table, for the U-lenses with a pixel dimension 3.18 μm and 2.4 μm, whether the U-lenses are located in the central location or the edge location of the wafer, the gap between the surface structure of neighboring U-lenses is reduced but the radius of curvature of the surface structure of the U-lenses is increased after forming the passivation layer. Using the U-lens having a pixel dimension 3.18 μm and located at the central location of the wafer as an example, the gap between U-lenses structure is 0.354 μm and the radius of curvature is 2.154 μm before forming the passivation layer. After forming the passivation layer, the gap between U-lenses is reduced to 0.196 μm and the radius of curvature is increased to 2.444 μm. Therefore, forming a passivation layer over the U-lenses is capable of reducing the gap between neighboring U-lenses and increasing the radius of curvature so that the area in the U-lenses for absorbing incident light is increased.

In summary, major advantages of the present invention at least includes:
1. The passivation layer formed over the U-lenses in the process of fabricating the image sensor can prevent the damaging effects of the micro-particles and other contaminants.
2. With passivation covering the U-lenses, the U-lenses are structurally protected against any damages during the subsequent wafer cleaning operation.
3. The passivation layer can reduce the gaps between neighboring U-lenses or remove the gap altogether.
4. The passivation layer over the U-lenses can increase the area for absorbing incident light, and reduce cross-talk between the incident light rays. Hence, the noise received by the CMOS transistor image sensor is reduced and the sensing capacity of the device is improved.
5. Due to the applied pressure at the condition of the present invention in the process of fabricating the passivation layer, the passivation layer has a smaller stress value. As a result, the chance of producing cracks on the U-lenses is substantially reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating an image sensor on a semiconductor substrate having a sensor array, the fabricating method comprising steps of:
forming a first planar layer on the semiconductor substrate;
forming a color filter array on the first planar layer, wherein the color filter array is formed above the corresponding sensor array area;
forming a second planar layer on the color filter array;
forming a plurality of U-lenses on the second planar layer, wherein the U-lenses are formed above the corresponding color filter array; and
performing a plasma-enhanced chemical vapor deposition process using tetraethosiloxane (TEOS) as a reactive gas to form a conformal passivation layer over the U-lenses and the second planar layer, wherein the passivation layer is formed under the conditions that include applying radio frequency at a power rating between about 250 W˜450 W and passing TEOS gas at a mass flow rate between 150˜500 mg/m.

2. The method of claim 1, wherein the processing temperature of the passivation layer is between 150° C.˜250° C.

3. The method of claim 1, wherein the process of forming the passivation layer includes passing oxygen and helium.

4. The method of claim 3, wherein the volume flow rate of the oxygen and helium includes 1000 sccm.

5. The method of claim 1, wherein the image sensor includes a complementary metal-oxide-semiconductor (CMOS) transistor image sensor.

6. The method of claim 1, wherein the color filter array includes a R/G/B color filter array.

7. The method of claim 1, wherein after forming the passivation layer, further includes forming a bond pad opening outside the sensor array area.

8. A method of fabricating an image sensor on a semiconductor substrate having a sensor array, the fabricating method comprising steps of:
forming a first planar layer on the semiconductor substrate;
forming a color filter array on the first planar layer, wherein the color filter array is formed above the corresponding sensor array area;
forming a second planar layer on the color filter array;
forming a plurality of U-lenses on the second planar layer, wherein the U-lenses are formed above the corresponding color filter array; and
performing a plasma-enhanced chemical vapor deposition process using tetraethosiloxane (TEOS) as a reactive gas to form a conformal passivation layer over the U-lenses and the second planar layer, wherein the passivation layer is formed under the conditions that include applying radio frequency at a power rating between about 250 W˜450 W, applying a pressure of between 2˜4 Torrs and passing TEOS gas at a mass flow rate between 150˜500 mg/m.

9. The method of claim 8, wherein the processing temperature of the passivation layer is between 150° C.˜250° C.

10. The method of claim 8, wherein the process of forming the passivation layer includes passing oxygen and helium.

11. The method of claim 10, wherein the volume flow rate of the oxygen and helium includes 1000 sccm.

12. The method of claim 8, wherein the image sensor includes a complementary metal-oxide-semiconductor (CMOS) transistor image sensor.

13. The method of claim 8, wherein the color filter array includes a R/G/B color filter array.

14. The method of claim 8, wherein after forming the passivation layer, further includes forming a bond pad opening outside the sensor array area.
